(19) United States
(12) Patent Application Publication
(10) Pub. No.: US 2001/0044166 A1
(43) Pub. Date: Nov. 22, 2001

(54) METHOD FOR FORMING MICROLENSES WITH HIGH LIGHT TRANSMITTANCE IN IMAGE SENSOR

(76) Inventors: KI-YEOP PARK, KYOUNGKI-DO (KR); SANG-GIL BAE, KYOUNGKI-DO (KR)

Correspondence Address: BLAKELY SOKOLOFF TAYLOR & ZAFMAN LLP, 12400 WILSHIRE BOULEVARD, 7TH FLOOR, LOS ANGELES, CA, 900251026

(21) Appl. No.: 09/475,011

(22) Filed: Dec. 30, 1999

(30) Foreign Application Priority Data
Dec. 30, 1998 (KR) 1998-61087

(51) Int. Cl. H01L 21/00

(52) U.S. Cl. 438/60; 438/69; 438/71

(57) ABSTRACT

There is provided a method for forming microlenses in an image sensor having high light transmittance in short wavelength regions of visible lights, the method comprising: depositing a resist film for microlens over a predetermined substrate; selectively first-exposing the resist film to light in a range of exposure wavelengths and developing it to form resist patterns; second-exposing the remaining resist patterns to light photochemically to decompose an active form of sensitisizer remained in the resist patterns into an inactive form; and heating and flowing the resist patterns to form microlenses.

### FIELD OF THE INVENTION

The present invention relates to a method for fabricating an image sensor; and more particularly to a method for forming microlenses in an image sensor.

### DESCRIPTION OF THE PRIOR ART

Generally, an image sensor is a semiconductor element to convert optical images into electric signals. A double charge coupled device (CCD) in which each Metal-Oxide-Silicon (MOS) capacitor is located proximate to each other, stores charge carriers in the capacitor and transports them. A complementary MOS (CMOS) image sensor is to be made of MOS transistors as many as the number of pixels by using the CMOS technique employing control circuit and signal processing circuit as peripheral circuit and is to employ the switching manner detecting output, in turn.

In fabrication of these various image sensors, there have been proceeded endeavors to increase the photosensitivity of image sensors. One among them is the light-collecting technique. In more detail, the image sensor includes the photosensitive parts sensing the lights and accumulating photocharges and logic circuit parts transforming the photocharges into electric signals and generating data. To improve the photosensitivity of the image sensor, there have been proceeded endeavors to increase the area ratio (fill factor) of the photosensitive parts in the whole image sensor. However, there are fundamentally limits in such endeavors, because the logic circuit parts can not be completely eliminated and thus, the photosensitive parts exist in a limited area. Accordingly, in order to increase the photosensitivity, light-collecting technique has been appeared, by which the pathways of the incident lights injecting to the regions other than the photosensitive parts are changed and collected in the photosensitive parts. For the light collecting, the image sensor includes microlenses on the color filters.

FIGS. 1a to 1c are sectional views showing the method for forming microlenses according to the prior art. There will be described the prior art and its problems below, referring the drawings.

At first, referring to FIG. 1a there is provided a predetermined substrate (not shown), on which the related elements of image sensor including photosensitive elements such as photodiodes are formed. Color filter array 1 is then formed over the substrate. A resist film 2 for microlens is then deposited on the color filter array 1. Subsequently, the resist film 2 is partly and selectively exposed to ultraviolet (UV) light 4 by means of reticle 3.

Next, the resist film 2 is developed to remove its exposed parts. Thus, the resist patterns 2a are formed in the desirable form as shown in FIG. 2b. The resist patterns 2a are heated and flowed to form microlenses 2b in the form of half ball-like or half cylinder-like.

Meanwhile, when the microlens is bad in transmittance, the photosensitivity enhancement of the image sensor is restricted to the transmittance of microlens, although the microlens has an excellent light-collecting ability. In case of using a positive resist, which is to form patterns in the unexposed regions with removing the exposed regions by developing, there is left photosensitizer unchanged in the patterns from the unexposed regions. The photosensitizer itself can not absorb the lights in the visible regions. However, after the resist is baked at about 150° C. to form the microlenses, the transparent resist is changed into yellowish and thus, absorbs the lights in the visible regions.

FIG. 3 is a graph showing the transmittance of the yellowish resist. As shown in the drawing, the light transmittance is not good in the short wavelength regions of visible lights. In that case, the photosensitivity may be deteriorated due to the differences of sensitivities according to the wavelength of light and the color separation degree may be also decreased by becoming yellowish.

### SUMMARY OF THE INVENTION

It is, therefore, an object of the present invention to overcome the problems of the prior art described above, and to provide a method for forming microlenses in an image sensor having high light transmittance in short wavelength regions of visible lights.

In accordance with an aspect of the present invention, there is provided a method for forming microlenses in an image sensor, comprising: depositing a resist film for microlens over a predetermined substrate; selectively first-exposing the resist film to light in a range of exposure wavelengths and developing it to form resist patterns; second-exposing the remaining resist patterns to light photochemically to decompose an active form of sensitizer remained in the resist patterns into an inactive form; and heating and flowing the resist patterns to form microlenses.

### BRIEF DESCRIPTION OF THE DRAWINGS

The above and other objects and features of the present invention will become apparent from the following description of preferred embodiment given in conjunction with the accompanying drawings, in which:

FIGS. 1a to 1c are cross-sectional views showing the method for forming microlenses according to the prior art;

FIGS. 2a to 2c are cross-sectional views showing the method for forming microlenses according to one embodiment of the present invention;

FIG. 3 is an experimental graph showing the light transmittance of the yellowish resist formed according to the prior art;

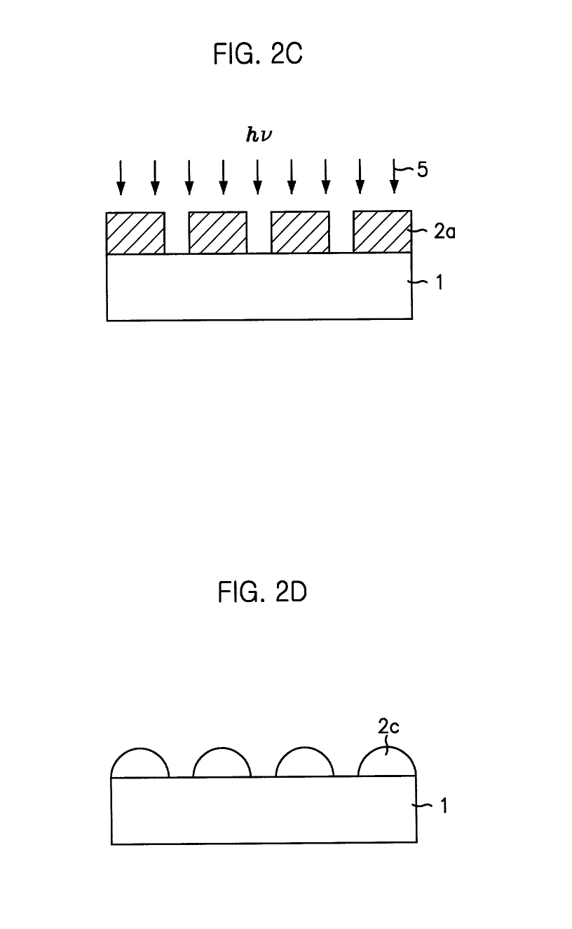

FIG. 4 is an experimental graph showing the light transmittance of the resist formed according to one embodiment of the present invention, the light transmittance being compared with that of the resist treated without bleaching process or treated with beaching process after thermal treatment.

### DETAILED DESCRIPTION OF THE PREFERRED EMBODIMENTS

The invention will be illustrated in detail by the following preferred embodiment with reference to the accompanying drawings.

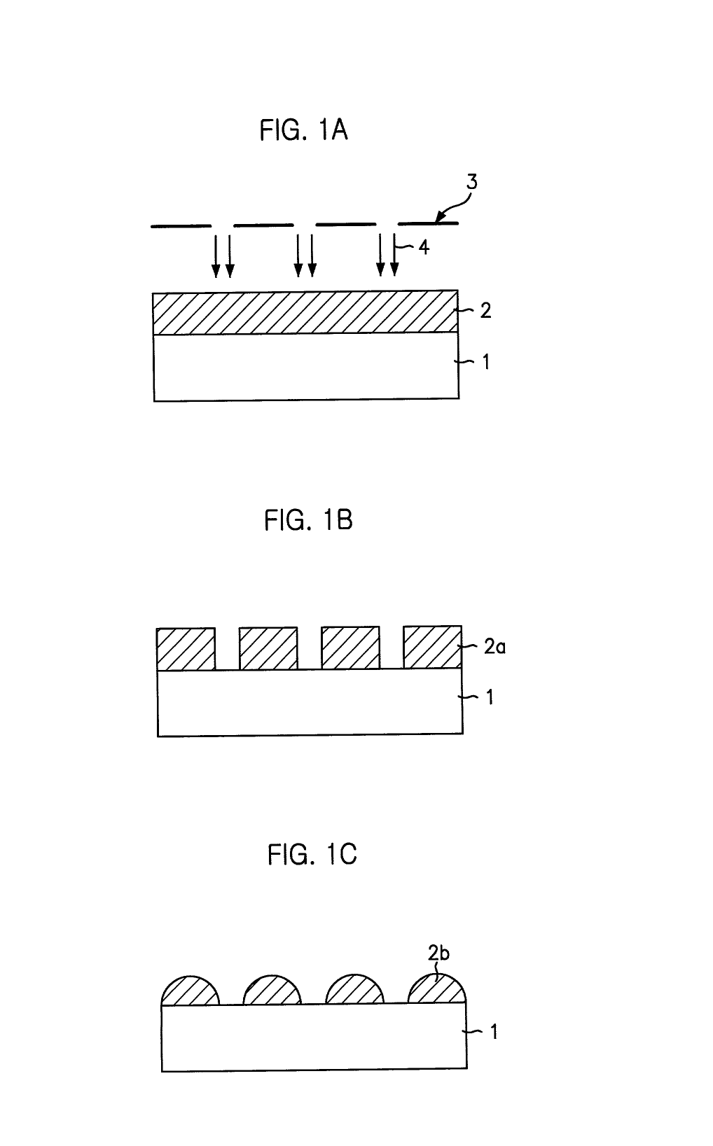

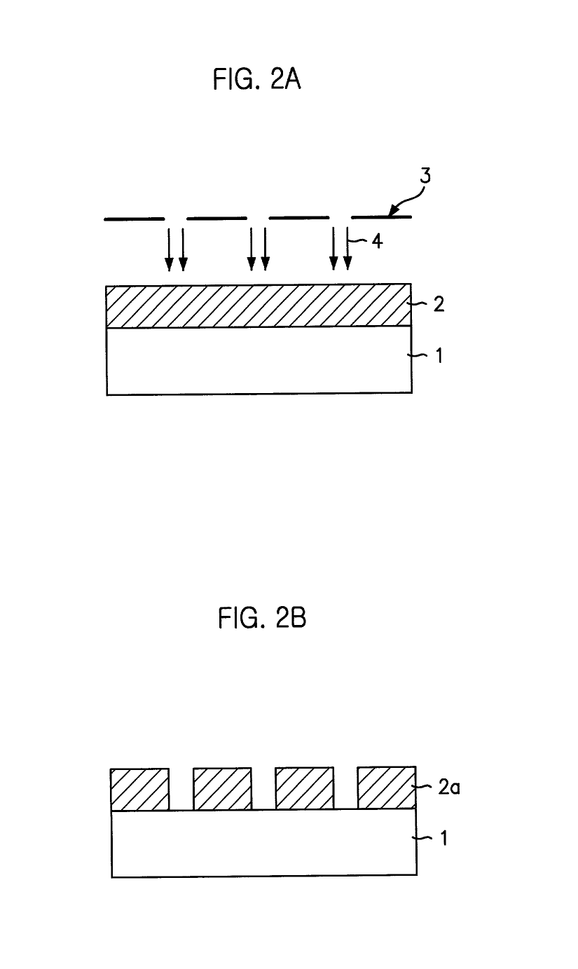

FIGS. 2a to 2c are cross-sectional views showing the method for forming microlenses according to one embodiment of the present invention. In the drawings, the same numerals are used for the same elements as depicted in FIGS. 1a to 1c.

At first, referring to FIG. 2a there is provided a predetermined substrate (not shown), on which the related elements of image sensor including photosensitive elements such as photodiodes are formed. In more detail, the predetermined substrate including the elements may be, for example, prepared by the following procedure. A field insulating film is formed on a silicon substrate and a photodiode as a photosensitive element is formed. After that, interlayer-insulating film is deposited and metal wire is formed. Subsequently, in order to protect the element from moisture or scratch, an oxide film and a nitride film are, in turn, deposited to form element-protecting film.

Color filter array 1 is then formed over the substrate. A resist film 2 for microlens is then deposited on the color filter array 1. Subsequently, the resist film 2 is partly and selectively exposed to UV light 4 by means of reticle 3 (first exposure).

Next, the resist film 2 is developed to remove its exposed parts. Thus, the resist patterns 2a are formed in the desirable form as shown in FIG. 2b. At this time, the resist patterns are not exposed to light and thus have photochemically unchanged photosensitizer.

Referring to FIG. 2c, the resist patterns 2a are then exposed again to the ultra-violet (UV) light 5 photochemically to decompose photosensitizer in the resist pattern (second exposure). At this time, the light wavelength is preferably in a range of the first exposure wavelength ±300 nm. The light energy is also preferably 50 mj/cm² or more. The second exposure is preferably performed two times.

The resist patterns 2a are heated and flowed to form microlenses 2b in the form of half ball-like or half cylinder-like. At this time, the formed microlenses 2c do not become yellowish unlikewise the microlenses of the prior art.

When the sensitizer in the resist patterns is heated without further exposure to light, it makes the resist patterns yellowish. It is considered this is caused from that the sensitizer such as diazonaphtoquinone left in the resist patterns is reacted with the polymer of resist or self-reacted, that is decomposed by the thermal treatment to be changed into the material absorbing the visible light.

As described above, the present invention is to enhance the light transmittance of the microlens in the visible light regions by decomposing the sensitizer in the resist patterns before heating the resist patterns to flow. That is, after the formation of the resist patterns 2a, they are exposed to the light 5 in a wavelength range of reacting the sensitizer to decompose it. Thus, the resist patterns do not become yellowish although the thermal treatment is performed after the decomposition of the sensitizer.

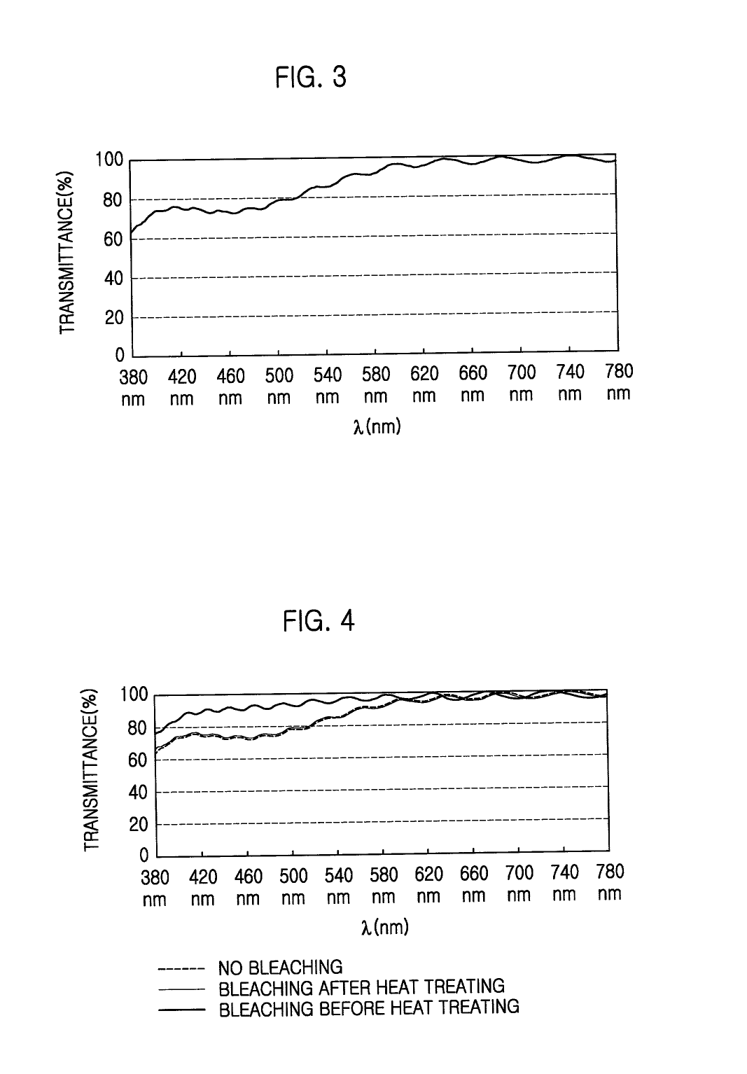

The process of decomposing the sensitizer by exposing it to light (hereinafter, called as bleaching process, simply) should be performed before the thermal treatment for flowing. The bleaching process does not make effects after the thermal treatment. The transmittances of the following cases are measured and shown in FIG. 4: the case of resist patterning, bleaching and thermal treating, in turn, the case of resist patterning, thermal treating and bleaching, in turn, and the case of resist patterning and thermal treating without bleaching. As shown in FIG. 4, the case of bleaching after thermal treating can not almost enhance the transmittance, in comparison with the case without bleaching. While, the case of bleaching before thermal treating according to the present invention can enhance the transmittance particularly in the short wavelength.

While the present invention has been described with respect to certain preferred embodiment only, other modifications and variations may be made without departing from the spirit and scope of the present invention as set forth in the following claims.

What is claimed is:

1. A method for forming microlenses in an image sensor, comprising:
depositing a resist film for microlens on a predetermined substrate;
selectively first-exposing the resist film to light in a range of exposure wavelengths and developing it to form resist patterns;
second-exposing the remaining resist patterns to light photochemically to decompose an active form of sensitisizer remained in the resist patterns into an inactive form; and
heating and flowing the resist patterns to form microlenses.

2. The method according to claim 1, wherein the step of second-exposure is performed before the step of thermal treatment.

3. The method according to claim 1, wherein the resist is a positive resist.

4. The method according to claim 1, wherein the used light in second exposure is light in a range of the exposure wavelength for resist patterning ±300 nm.

5. The method according to claim 1, wherein the used light in second exposure has energy of 50 mj/cm² or more.

6. The method according to claim 1, wherein the step of second exposure is performed at least two times.
